(19) United States
(12) Patent Application Publication
(10) Pub. No.: US 2004/0243323 A1
(43) Pub. Date: Dec. 2, 2004

(54) Electronic system with sensors

(75) Inventors: Frank Kuenzler, Kraichtal (DE); Bernd Biehlman, Ludwigsburg (DE); Heinrich Gotzig, Heilbronn (DE); Timo Hammel, Brackenheim (DE)

Correspondence Address: Dreiss, Fuhlendorf, Steimle & Becker, Postfach 10 37 62, D-70032 Stuttgart, DE

(73) Assignee: Valeo Schalter and Sensoren GmbH, Bietigheim-Bissingen (DE)

(21) Appl. No.: 10/834,914

(22) Filed: Apr. 30, 2004

(30) Foreign Application Priority Data
May 27, 2003 (DE) 103 25 374.2

(51) Int. Cl. G01R 21/00

(52) U.S. Cl. 702/62

(57) ABSTRACT

The invention relates to an electronic system (30) comprising a number of sensors (32, 34, 36, 38), a sensor (38) for use in such a system (30) and a method for controlling the electronic system (30). The electronic system (30) comprises a number of sensors (32, 34, 36, 38), one of which is designed as a master sensor (38).

This application claims Paris Convention priority of DE 103 25 374.2 filed May 27, 2003 the complete disclosure of which is hereby incorporated by reference.

### BACKGROUND OF THE INVENTION

The invention concerns an electronic system with a number of sensors and a method for controlling an electronic system.

Sensor systems are designed such that several sensors are connected to an ECU (electronic control unit). The ECU evaluates information from the individual sensors and transmits results to the driver of a motor vehicle or to other motor vehicle systems. In detail, the ECU can assume the following functions: signal processing, communication with the sensors, control of the sensors, diagnosis within the sensor system, storing of data, evaluation of errors, monitoring of the sensors and communication with the vehicle or other vehicle systems via an interface. The ECU thereby contains corresponding components which permit performance of such functions or tasks. Such a component may e.g. be designed as microcontroller, digital signal processor (DSP), interface component, voltage supply, filter means or the like.

The ECU is an expensive component within the sensor system. For this reason, it is the task of a person skilled in the art to reduce costs associated therewith.

### SUMMARY OF THE INVENTION

This object is achieved with an electronic system and method comprising the features of the independent claims.

The invention concerns an electronic system comprising a plurality of sensors, wherein at least one of the sensors is designed as a master sensor which receives and suitably further processes data detected by the other sensors. The sensory function permits sensor detection of environmental events or influences and provision of distinct sensor signals or sensor data on the basis thereof. The master sensor is designed to receive and suitably further process or evaluate data detected from the sensors and transfer it to another device outside of the system.

Moreover, the master sensor may receive data from other electronic units of the electronic system and process it in a suitable fashion. Another electronic unit may e.g. be an actor which carries out commands from the master sensor.

In a preferred embodiment, the master sensor is designed to control at least one sensor. Due to its design, the master sensor may also assume control functions, data transfer functions and/or data processing functions comparable to an ECU, in addition to detection of events or conditions.

The communication means are preferably provided to exchange data between the sensors. These communication means may be designed as suitable data lines. Communication between sensors may also be provided through radio transmission. Data, signals or processed information are transmitted via communication means. The master sensor can thereby transmit control commands for influencing other sensors of the system. The communication means may additionally be connected to system-external devices to permit reception as well as transmission of data from the outside and to the outside.

In a further embodiment of the invention, the master sensor has at least one electronic means for information processing. This at least one electronic means may be designed as an integrated microcontroller, digital signal processor or the like. Electronic means which have been previously disposed within the ECU may now be disposed within the master sensor in accordance with the invention. The at least one electronic means of the inventive master sensor may be designed for processing signals and/or for communication with the at least one electronic means and/or for the control of the at least one electronic means and/or for diagnosis of the at least one electronic means and/or for storing data and the like. The master sensor is preferably provided with corresponding electronic means to assume supervisory tasks similar to those of an ECU. Such an electronic means may be a microcontroller, processor, e.g. a digital signal processor.

In a preferred embodiment, the master sensor is provided as sensor comprising modified hardware and/or software such as e.g. a more powerful processor and/or a more powerful voltage processing means than in a conventional sensor. This measure achieves the aim of the invention through modification of means which are already present within a sensor. Such an upgrading of the sensor into a master sensor can be carried out inexpensively.

In a preferred embodiment of the electronic system, the master sensor may comprise at least one interface for connecting the at least one electronic means to a communication means. This measure permits exchange of data within the electronic system, in particular of data which is further processed by the master sensor.

The inventive sensor assumes central and supervisory tasks for controlling the inventive system e.g. processing and/or evaluation of signals and data produced within the electronic system. The electronic system may be designed as a sensor system. At least one further sensor of the sensor system assumes the function of a slave sensor which can be controlled by the master sensor.

The inventive sensor system may be designed as a traffic environment detection system comprising several channels. Such an electronic system may be designed as a component of a motor vehicle and can be disposed e.g. within a bumper system of a motor vehicle.

The invention is preferably used in systems having intelligent sensors. This includes sensors comprising an integrated microcontroller and/or DSP (digital signal processor). The resources present in such a sensor can thereby be utilized more effectively. The master sensor can thereby assume the tasks of the ECU. In a particularly preferred fashion, the application of the invention is suited for systems which process only a small amount of signals and/or data. In this case, the ECU can be replaced in a particularly simple manner by an inventive master sensor.

In accordance with the invention, a sensor is defined as master sensor within the sensor system, and the other sensors are correspondingly defined as slave sensors. It is, however, feasible to distribute functions of the ECU, which are rendered unnecessary by the inventive measures, among several sensors having appropriate electronic means and/or which are appropriately modified.

The inventive method controls an electronic system comprising a number of sensors. One of the sensors is thereby designed as so-called master sensor and receives and suitably further processes the data detected by other sensors.

The inventive measures permit elimination of a number of components which have been necessary up to now to provide various functions in the electronic system. These include i.a. processor, voltage supply, cabling, housing, assembly and printed circuit board of the ECU.

The somewhat more powerful components of the inventive master sensor are thereby considerably less expensive than the omitted components of the ECU. The invention therefore considerably reduces the costs of a sensor system. The omission of the ECU or of its components has moreover a positive effect on a motor vehicle, since the vehicle thereby becomes less massive.

The invention permits processing of signals from several sensors and transmitting the resulting information to the driver or to other systems of the vehicle without requiring an external control device, in particular, a conventional ECU.

The inventive concept can be applied to various sensors (e.g. radar, ultrasound, optical sensors and the like). Sensors comprising integrated signal processing and/or microcontrollers reduce the costs to an even greater extent.

Further advantages and embodiments of the invention can be extracted from the description and the accompanying drawing.

It is clear that the features mentioned above and below can be applied not only in the respectively stated combination, but also in other combinations or individually without departing from the scope of the present invention.

The invention is schematically shown in the drawing by means of an embodiment, and is described below in more detail with reference to the drawing.

### BRIEF DESCRIPTION OF THE DRAWING

FIG. 1 shows a simple schematic view of a sensor system in accordance with prior art; and

FIG. 2 shows a schematic view of a preferred embodiment of a sensor system with a preferred embodiment of an inventive master sensor.

### DESCRIPTION OF THE PREFERRED EMBODIMENT

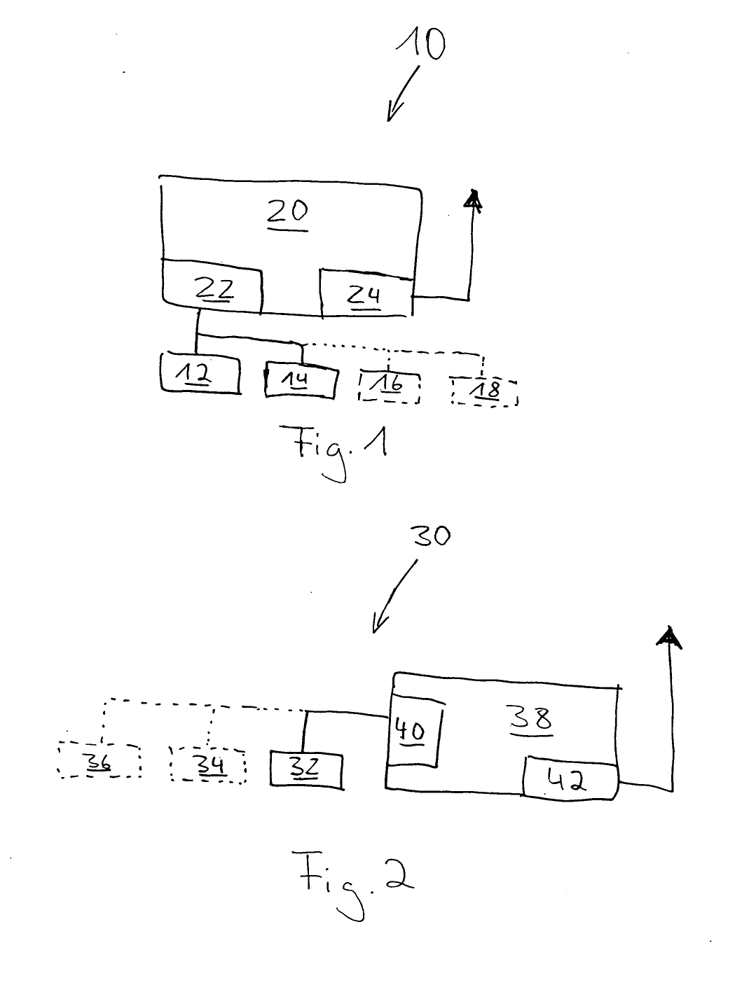

FIG. 1 schematically shows a conventional sensor system according to prior art which is designated in its entirety with 10. The sensor system 10 comprises at least two sensors 12, 14 and can also be extended with further sensors 16, 18.

The central unit of the sensor system 10 according to prior art is an ECU 20 which comprises a communication sensor 22 and a communication means 24. The ECU 20 is only designed to process signals and data resulting from signals. The communication sensor 22 is connected to the sensors 12, 14 or 16, 18 via suitable connecting leads. The signals derived from detected data can be transmitted by the communication means 24 through a communication line to the driver of a motor vehicle and to other motor vehicle systems. A conventional sensor system 10 can be realized only with considerable costs due to the fact that the ECU 20 is required.

FIG. 2 shows a preferred embodiment of the inventive sensor system which is designated in its entirety with reference numeral 30 and which comprises no ECU.

The inventive sensor system 30 of FIG. 2 comprises sensors, which are designed, in particular, as slave sensors 32, 34, 36, comparable to the sensors 12, 14, 16, 18 of the sensor system 10 of prior art of FIG. 1. Depending on the application, these slave sensors 32, 34, 36 may be largely of the same construction as sensors 12, 14, 16, 18 and may assume largely identical functions.

In the inventive sensor system 30, a master sensor 38 has the structural and functional features of the ECU 20 of the conventional sensor system 10, which can assume the function of a conventional sensor 12, 14, 16, 18 or slave sensor 32, 34, 36. Moreover, the master sensor 38 also assumes the functions of the ECU 20.

The master sensor 38 comprises a communication sensor 40, which is designed as an interface and which is connected to at least the slave sensor 32, and optionally to the slave sensors 34, 36, through a suitable communication line to provide data transfer. The master sensor 38 additionally comprises a communication means 42 via which it is connected to the driver of the vehicle and to other systems of the vehicle through a suitable communication line for data exchange.

The master sensor 38 may be a conventional sensor having additional electronic means or largely conventional electronic means which are more powerful in accordance with the invention such that the master sensor 38 of the inventive sensor system 30 can replace the ECU 20 of the conventional sensor system 10 while thereby providing equivalent functions. The sensor processor already used for signal processing can thereby assume the function of the processor of the ECU 20 within the inventive master sensor 38.

In a specific application, a largely conventional sensor may be used as the master sensor 38 which has, however, improved calculation power compared to a conventional sensor. If not present in the conventional sensor, the master sensor 38 may be provided with a processor preferably comprising two interfaces to provide communication to the driver, other systems of the vehicle and other sensors, in particular slave sensors 32, 34, 36.

The inventive sensor system 30 comprising the master sensor 38 has considerable advantages compared to the sensor system 10. Omission of the housing, of the processor, of an interface and/or PCB (printed circuit board) of the ECU 20 reduces costs and weight compared to a conventional sensor system 10. Moreover, the size of the cable harness can be reduced.

A bumper system for a motor vehicle comprising the inventive sensor system 10 can be supplied to the vehicle manufacturing industry in the form of a finished complete module, to provide the vehicle manufacturing industry with a self-contained bumper system. Conventional bumpers comprising a conventional sensor system 10 have the disadvantage that an ECU 20 must be provided outside of the bumper.

The inventive sensor system 30 can be designed e.g. as a radar parking assistance, consisting of a master sensor 38 and any number of slave sensors 32, 34, 36, typically of up to nine. A corresponding sensor system 10 in accordance with prior art must comprise, in addition to the ECU 20, at least one sensor 12, 14, 16, 18 more than the inventive sensor system 30 to provide the same sensory functions.

We claim:

1. An electronic system, comprising:
at least one slave sensor; and
at least one master sensor communicating with said at least one slave sensor to receive and further process data detected by said slave sensor.

2. The electronic system of claim 1, further comprising at least one further electronic unit, wherein said master sensor receives and further processes data from said at least one further electronic unit.

3. The electronic system of claim 1, wherein said, master sensor is designed to control said at least one slave sensor.

4. The electronic system of claim 1, further comprising communication means for exchanging data between said master sensor and said slave sensor.

5. The electronic system of claim 4, wherein said master sensor comprises at least one electronic means for processing information.

6. The electronic system of claim 5, wherein said master sensor comprises at least one interface for connecting said at least one electronic means to said communication means.

7. The electronic system of claim 6, wherein said at least one electronic means comprises two interfaces for connecting to said communication means.

8. The electronic system of claim 1, wherein the system is designed as a traffic environment detection system comprising several channels.

9. The electronic system of claim 1, wherein the system is structured and dimensioned as a component of a motor vehicle.

10. The electronic system of claim 9, wherein the system is part of a bumper of the motor vehicle.

11. The master sensor of claim 1.

12. A method for controlling the electronic system of claim 1.
